(19) United States
(12) Patent Application Publication
(10) Pub. No.: US 2013/0308287 A1
(43) Pub. Date: Nov. 21, 2013

(54) POWER DEVICE AND PACKAGE FOR POWER DEVICE

(71) Applicant: Hideaki Nezu, Tsukuba-shi (JP)

(72) Inventor: Hideaki Nezu, Tsukuba-shi (JP)

(73) Assignee: SUMITOMO CHEMICAL COMPANY, LIMITED, Chuo-ku, Tokyo (JP)

(21) Appl. No.: 13/982,049

(22) PCT Filed: Jan. 26, 2012
(86) PCT No.: PCT/JP2012/051645

§ 371 Date: Jul. 26, 2013

(30) Foreign Application Priority Data
Jan. 28, 2011 (JP) 2011-016247

(51) Int. Cl. H05K 1/18

(52) U.S. Cl. CPC H05K 1/181
USPC 361/783

(57) ABSTRACT

The present invention addresses the problem of providing a power device comprising a terminal-holding member excellent in insulating properties. The present invention relates to a power device having a power element, a terminal, and a terminal-holding member composed of a liquid crystalline polyester, wherein the liquid crystalline polyester is a liquid crystalline polyester having a repeating unit (1) derived from an aromatic hydroxycarboxylic acid, a repeating unit (2) derived from an aromatic dicarboxylic acid, and a repeating unit (3) derived from an aromatic diol, and the content of a repeating unit derived from isophthalic acid in the liquid crystalline polyester is 0 to 7 mol % relative to the total amount of all repeating units of the liquid crystalline polyester.

### TECHNICAL FIELD

The present invention relates to a power device having a terminal-holding member composed of a liquid crystalline polyester. The present invention also relates to a package for a power device used as a package for this power device.

### BACKGROUND ART

A power device usually has a power element, a terminal which is electrically connected to the power element, and a terminal-holding member for holding the terminal. An example of the power device is shown in FIGS. 1 and 2. In the example of FIG. 1, a power module is fixed on a heat radiating plate 5 of a package for a power device; in the power module, power elements 1, 1 are fixed on a printed wiring board 2, and an electrode of the power elements 1, 1 is connected to wiring of the printed wiring board 2 with a wire; the package for a power device has terminals 3, 3, terminal-holing members 4, 4 and the heat radiating plate 5; wiring of the printed wiring board 2 is connected to the terminals 3, 3with a wire; and the power module is sealed with a sealing material 6. In the example of FIG. 2, a power element 1 is fixed on a pad 7, an electrode of a power element 1 is connected to terminals 3, 3 with a wire, the terminals 3, 3 are held with a terminal-holding member also functioning as a sealing material 8 and, at the same time, the power element 1 is sealed with the material 8.

As a material of the terminal-holding member, due to excellent heat resistance, a liquid crystalline polyester is studied. For example, Patent Document 1 discloses a terminal-holding member composed of a liquid crystalline polyester (“Vectra C950” from Hoechst AG) having 80 mol % of a repeating unit derived from p-hydroxybenzoic acid and 20 mol % of a repeating unit derived from 6-hydroxy-2-naphthoic acid.

### PRIOR ART DOCUMENT

### Patent Document

Patent Document 1: JP-A-3-126765

### SUMMARY OF THE INVENTION

### Problems to be Solved by the Invention

The conventional power device having a terminal-holding member composed of a liquid crystalline polyester as disclosed in Patent Document 1 is not necessarily sufficient in insulating property of the terminal-holding member and, particularly, it has a problem that insulation breakdown is easily generated when the distance between adjacent terminals is short. Accordingly, an object of the present invention is to provide a power device having a terminal-holding member, in which the member is composed of a liquid crystalline polyester and is excellent in insulating property, and in which insulation breakdown is hardly generated even when the distance between adjacent terminals is short.

### Means for Solving the Problems

The present invention was made in order to attain the aforementioned object, and includes the following preferable embodiments.

[1] A power device having a power element, a terminal, and a terminal-holding member composed of a liquid crystalline polyester, wherein the liquid crystalline polyester is a liquid crystalline polyester having a repeating unit (1) derived from an aromatic hydroxycarboxylic acid, a repeating unit (2) derived from an aromatic dicarboxylic acid, and a repeating unit (3) derived from an aromatic diol, and the content of a repeating unit derived from isophthalic acid in the liquid crystalline polyester is 0 to 7 mol % relative to the total amount of all repeating units of the liquid crystalline polyester.

[2] The power device according to [1], wherein the repeating unit (1) is a repeating unit derived from p-hydroxybenzoic acid or 6-hydroxy-2-naphthoic acid, the repeating unit (2) is a repeating unit derived from terephthalic acid, isophthalic acid or 2,6-naphthalenedicarboxylic acid, and the repeating unit (3) is a repeating unit derived from hydroquinone or 4,4′-dihydroxybiphenyl.

[3] The power device according to [1] or [2], wherein the liquid crystalline polyester is a liquid crystalline polyester having the repeating unit (1) in an amount of 30 to 80 mol %, the repeating unit (2) in an amount of 10 to 35 mol %, and the repeating unit (3) in an amount of 10 to 35 mol % relative to the total amount of all repeating units of the liquid crystalline polyester.

[4] The power device according to any one of [1] to [3], wherein the terminal-holding member is a member containing a glass fiber.

[5] The power device according to [4], wherein the content of the glass fiber in the terminal-holding member is 10 to 100 parts by mass relative to 100 parts by mass of the liquid crystalline polyester.

[6] The power device according to any one of [1] to [5], wherein the distance between the adjacent terminals is 0.2 to 1.5 mm.

[7] A package for a power device having a terminal, and a terminal-holding member composed of a liquid crystalline polyester, wherein the liquid crystalline polyester is a liquid crystalline polyester having a repeating unit (1) derived from an aromatic hydroxycarboxylic acid, a repeating unit (2) derived from an aromatic dicarboxylic acid, and a repeating unit (3) derived from an aromatic diol, and the content of a repeating unit derived from isophthalic acid in the liquid crystalline polyester is 0 to 7 mol % relative to the total amount of all repeating units of the liquid crystalline polyester.

[8] The package for a power device according to [7], wherein the repeating unit (1) is a repeating unit derived from p-hydroxybenzoic acid or 6-hydroxy-2-naphthoic acid, the repeating unit (2) is a repeating unit derived from terephthalic acid, isophthalic acid or 2,6-naphthalenedicarboxylic acid, and the repeating unit (3) is a repeating unit derived from hydroquinone or 4,4′-dihydroxybiphenyl.

[9] The package for a power device according to [7] or [8], wherein the liquid crystalline polyester is a liquid crystalline polyester having the repeating unit (1) in an amount of 30 to 80 mol %, the repeating unit (2) in an amount of 10 to 35 mol %, and the repeating unit (3) in an amount of 10 to 35 mol % relative to the total amount of all repeating units of the liquid crystalline polyester.

[10] The package for a power device according to any one of [7] to [9], wherein the terminal-holding member is a member containing a glass fiber.

[11] The package for a power device according to [10], wherein the content of the glass fiber in the terminal-holding member is 10 to 100 parts by mass relative to 100 parts by mass of the liquid crystalline polyester.

[12] The package for a power device according to any one of [7] to [11], wherein the distance between the adjacent terminals is 0.2 to 1.5 mm.

### Effect of the Invention

The power device and the package for a power device of the present invention are excellent in insulating property of a terminal-holding member, and insulation breakdown is hardly generated even when the distance between adjacent terminals is short. For this reason, the power device and the package for a power device of the present invention are suitable for the case where the distance between adjacent terminals is 0.2 to 1.5 mm.

### BRIEF DESCRIPTION OF THE DRAWINGS

FIG. 1 is a cross-sectional view schematically showing an example of a power device.

FIG. 2 is a cross-sectional view schematically showing an example of a power device.

### MODE FOR CARRYING OUT THE INVENTION

The power device of the present invention has a power element, a terminal and a terminal-holding member. The terminal member is composed of a specific liquid crystalline polyester.

The power element is a semiconductor element for an electric power machine, and has a function of converting an electric current from alternate current to direct current, or from direct current to alternate current, and of controlling the electric current, voltage and frequency. The power element is generally a semiconductor element which controls a voltage of 200 V or more and an electric current of 20 A or more. Examples of the power element include a rectifying diode, a power transistor, a power MOSFET, an insulated gate bipolar transistor (IGBT), a thyristor, a gate turn off thyristor (GTO) and a triac.

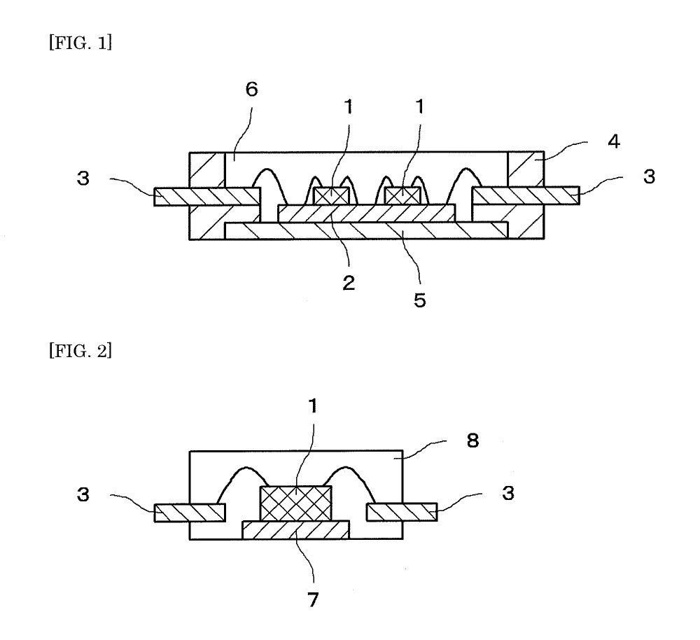

By mounting a plurality of power elements on a printed wiring board as shown in FIG. 1, or mounting a power element together with a control circuit, a driving circuit and a protecting circuit on a printed wiring board, the power element may be used as a so-called power module. Here, mounting of the power element on a printed wiring board is performed by fixing the power element on a printed wiring board with solder, an adhesive or the like, and connecting an electrode of the power element to wiring of the printed wiring board. This connection may be performed by connection with a wire made of a metal such as aluminum or copper as shown in FIG. 1, or by direct joining with solder or the like.

A terminal is used for connecting a power device, a power source and other instruments with one another, and is usually composed of a metal such as aluminum or copper. Usually, 2 to 20 terminals are disposed in the power device. Connection between an electrode of a power element and a terminal, and connection between wiring of a printed wiring board on which a power element is mounted and a terminal may be performed by connection with a wire made of a metal such as aluminum or copper as shown in FIGS. 1 and 2, or may be performed by direct joining with solder or the like.

A liquid crystalline polyester constituting a terminal-holding member is a liquid crystalline polyester exhibiting liquid crystallinity in a melted state, and is preferably a polyester liquid crystalline which melts at a temperature of 450° C. or lower. In the present invention, as a liquid crystalline polyester, a liquid crystalline polyester is used, which has a repeating unit (1) derived from an aromatic hydroxycarboxylic acid, a repeating unit (2) derived from an aromatic dicarboxylic acid, and a repeating unit (3) derived from an aromatic diol, and in which the content of a repeating unit derived from isophthalic acid being the repeating unit (2) is 0 to 7 mol % relative to the total amount of all repeating units. Thereby, a terminal-holding member, which is excellent in insulating property and in which insulation breakdown is hardly generated even when the distance between adjacent terminals is short, can be obtained. The content of the repeating unit derived from isophthalic acid is preferably 6 mol % or less, more preferably 4% or less, further preferably 3 mol % or less, and usually 1 mol % or more relative to the total amount of all repeating units. As this content is smaller, insulating property of the terminal-holding member is easily improved, but when the content is too small, it becomes difficult to mold a liquid crystalline polyester.

It is preferable that the repeating unit (1) is a repeating unit derived from p-hydroxybenzoic acid or 6-hydroxy-2-naphthoic acid, that the repeating unit (2) is a repeating unit derived from terephthalic acid, isophthalic acid or 2,6-naphthalenedicarboxylic acid, and that the repeating unit (3) is a repeating unit derived from hydroquinone or 4, 4′-dihydroxybiphenyl.

The content of the repeating unit (1) is usually 30 mol % or more, preferably 30 to 80 mol %, more preferably 40 to 70 mol %, further preferably 45 to 65 mol % relative to the total amount of all repeating units (a value obtained by obtaining a substance amount equivalent (mol) of each repeating unit by dividing the mass of each repeating unit constituting a liquid crystalline polyester by the formula weight of the repeating unit and summing up the substance amount equivalents). The content of the repeating unit (2) is usually 35 mol % or less, preferably 10 to 35 mol %, more preferably 15 to 30 mol %, further preferably 17.5 to 27.5 mol % relative to the total amount of all repeating units. The content of the repeating unit (3) is usually 35 mol % or less, preferably 10 to 35 mol %, more preferably 15 to 30 mol %, further preferably 17.5 to 27.5 mol % relative to the total amount of all repeating units. As the content of the repeating unit (1) is greater, melt flowability, heat resistance, strength and rigidity are easily improved, but when the content is too great, the melting temperature and melt viscosity easily increase, and the temperature necessary for molding easily increases.

The ratio between the content of the repeating unit (2) and the content of the repeating unit (3) is usually 0.9/1 to 1/0.9, preferably 0.95/1 to 1/0.95, more preferably 0.98/1 to 1/0.98, as expressed by [content of repeating unit (2)]/[content of repeating unit (3)] (mol/mol).

In addition, the liquid crystalline polyester may have two or more kinds of each of repeating units (1) to (3). In addition, the liquid crystalline polyester may have a repeating unit other than the repeating units (1) to (3), and the content thereof is usually 10 mol % or less, preferably 5 mol % or less relative to the total amount of all repeating units.

The liquid crystalline polyester can be produced by polymerizing (polycondensing) a monomer that gives the repeating unit (1), that is, an aromatic hydroxycarboxylic acid, a monomer that gives the repeating unit (2), that is, an aromatic dicarboxylic acid, and a monomer that gives the repeating unit (3), that is, an aromatic diol, so that the amount of isophthalic acid being an aromatic dicarboxylic acid becomes 0 to 7 mol % relative to the total amount of all monomers. In this case, in place of a part or all of each of the aromatic hydroxycarboxylic acid, the aromatic dicarboxylic acid and the aromatic diol, a polymerizable derivative thereof may be used. Examples of a polymerizable derivative of a compound having a carboxyl group such as an aromatic hydroxycarboxylic acid and an aromatic dicarboxylic acid include derivatives in which a carboxyl group has been converted into an alkoxycarbonyl group or an aryloxycarbonyl group, derivatives in which a carboxyl group has been converted into a haloformyl group, and derivatives in which a carboxyl group has been converted into an acyloxycarbonyl group. Examples of polymerizable derivatives of a compound having a hydroxyl group such as an aromatic hydroxycarboxylic acid and an aromatic diol include derivatives in which a hydroxyl group has been acylated to be converted into an acyloxyl group.

It is preferable that the liquid crystalline polyester is produced by melt-polymerizing a monomer and solid phase-polymerizing the resulting polymer (prepolymer). Thereby, a liquid crystalline polyester having high heat resistance and a high melt tension can be produced with good operability. Melt polymerization may be performed in the presence of a catalyst. Examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as N,N-dimethylaminopyridine and N-methylimidazole, and the nitrogen-containing heterocyclic compound is preferably used.

In the liquid crystalline polyester, the flow initiation temperature thereof is preferably 280° C. or higher, more preferably 290° C. or higher, further preferably 295° C. or higher, and usually 380° C. or lower, preferably 350° C. or lower. As the flow initiation temperature is higher, heat resistance and the melt tension are easily improved, but when the temperature is too high, a high temperature is required for melting, and the liquid crystalline polyester is easily thermally deteriorated upon molding.

The flow initiation temperature is also called as a flow temperature and is a temperature at which a melt viscosity of 4800 Pa·s (48,000 poises) is exhibited when a heated melt of the liquid crystalline polyester is extruded through a nozzle at a temperature elevation rate of 4° C./minute under a load of 9.8 MPa (100 kg/cm²) using a capillary rheometer having a nozzle of an internal diameter of 1 mm and a length of 10 mm. The flow initiation temperature serves as an index of the molecular weight of the liquid crystalline polyester (see “Liquid Crystal Polymer -Synthesis, Molding and Application-”, edited by Naoyuki Koide, CMC Publishing Co., Ltd., Jun. 5, 1987, p. 95).

The liquid crystalline polyester may be used as a liquid crystalline polyester composition by incorporating one or more kinds of other components such as a filler, an additive, and a resin other than the liquid crystalline polyester.

The filler may be a fibrous filler, a plate-like filler, or a spherical or other particulate filler other than the fibrous and plate-like fillers. In addition, the filler may be an inorganic filler or an organic filler. Examples of the fibrous inorganic filler include glass fibers; carbon fibers such as a pan-based carbon fiber and a pitch-based carbon fiber; ceramic fibers such as a silica fiber, an alumina fiber, and a silica alumina fiber; and metal fibers such as a stainless fiber. Examples of the fibrous inorganic filler also include whiskers such as a potassium titanate whisker, a barium titanate whisker, a wollastonite whisker, an aluminum borate whisker, a silicon nitride whisker, and a silicon carbide whisker. Examples of the fibrous organic filler include a polyester fiber and an aramid fiber. Examples of the plate-like inorganic filler include talc, mica, graphite, wollastonite, glass flake, barium sulfate and calcium carbonate. Mica may be white mica or gold mica, and may be fluorine gold mica or tetrasilicon mica. Examples of the particulate inorganic filler include silica, alumina, titanium oxide, glass bead, glass balloon, boron nitride, silicon carbide and calcium carbonate. The blending amount of the filler is usually 0 to 100 parts by mass relative to 100 parts by mass of the liquid crystalline polyester.

It is particularly preferable to blend a glass fiber into the liquid crystalline polyester to incorporate the glass fiber into the terminal-holding member since the strength of the terminal-holding member is easily improved. The amount of the glass fiber is preferably 10 to 100 parts by mass, more preferably 30 to 100 parts by mass, further preferably 30 to 80 parts by mass relative to 100 parts by mass of the liquid crystalline polyester. When the amount of the glass fiber is too small, the strength improving effect is insufficient, and when the amount is too large, anisotropy is easily generated. In addition, the glass fiber has a number average fiber diameter of preferably 25 μm or less, more preferably 20 μm or less, and a number average fiber length of preferably 500 μm or less, more preferably 300 μm or less. The number average fiber diameter and the number average fiber length of the glass fiber can be measured by observation with an electron microscope.

Examples of the additive include an antioxidant, a heat stabilizer, an ultraviolet absorber, an antistatic agent, a surfactant, a flame-retardant and a coloring agent. The blending amount of the additive is usually 0 to 5 parts by mass relative to 100 parts by mass of the liquid crystalline polyester.

Examples of the resin other than the liquid crystalline polyester include thermoplastic resins other than the liquid crystalline polyester such as polypropylene, polyamide, polyesters other than the liquid crystalline polyester, polysulfone, polyphenylene sulfide, polyether ketone, polycarbonate, polyphenylene ether, and polyether imide; and thermosetting resins such as a phenol resin, an epoxy resin, a polyimide resin, and a cyanate resin. The blending amount of the resin other than the liquid crystalline polyester is usually 0 to 20 parts by mass relative to 100 parts by mass of the liquid crystalline polyester.

It is preferable that the liquid crystalline polyester composition is prepared by melt-kneading the liquid crystalline polyester and other components which are used as necessary using an extruder, and extruding the melt into pellets. As the extruder, an extruder having a cylinder, one or more screws disposed in the cylinder, and one or more supply ports disposed in the cylinder is preferably used and, an extruder further having one or more vent portions disposed in the cylinder is more preferably used.

It is preferable that molding of the liquid crystalline polyester for a terminal-holding member is performed by a melt molding method, and it is more preferable that molding is performed by an injection molding method. Particularly, when molding is performed by a method of inserting a terminal into a mold and injecting the liquid crystalline polyester, that is, an insert molding method, the liquid crystalline polyester can be molded for the terminal-holding member and, at the same time, the terminal and the terminal-holding member can be integrated.

By integrating the terminal and the terminal-holding member, a package for a power device as shown in FIG. 1 is obtained. The package for a power device may have a member other than the terminal and the terminal-holding member. For example, by using a portion on which a power module is to be fixed as a heat radiating plate as shown in FIG. 1, heat generated from the power module can be effectively eliminated and, for example, when the package is disposed in an engine room or the like as a power device for an automobile and operated under a high temperature, this configuration is advantageous.

In addition, the terminal-holding member may also function as a sealing material of the power device as shown in FIG. 2, and the power device having this terminal-holding member also functioning as a sealing material is advantageously produced by a method of electrically connecting the power device to a terminal, inserting the resultant into a mold, and injecting the liquid crystalline polyester, that is, an insert molding method. The power device may have a member other than a power element, a terminal and a terminal-holding member. For example, as shown in FIG. 2, a portion on which a power element is to be fixed may be a pad which constitutes a lead frame together with terminals, and this pad may be served as a heat radiating plate.

The thus obtained power device making use of heat resistance and insulating property of the terminal-holding member thereof is used as an electric power machine in vehicles such as automobiles and electric trains, industrial machines, office automation equipment and home appliances for example and, particularly, is suitably used as an electric power machine for automobiles.

### EXAMPLES

[Measurement of Flow Initiation Temperature of Liquid Crystalline polyester]

Using a flow tester (“Model CFT-500” manufactured by Shimadzu Corporation), about 2 g of a liquid crystalline polyester was filled into a cylinder to which a die having a nozzle of an internal diameter of 1 mm and a length of 10 mm had been attached, and the liquid crystalline polyester was melted under a load of 9.8 MPa (100 kg/cm²) while the temperature was elevated at a rate of 4° C./minute. The liquid crystalline polyester was extruded through the nozzle and the temperature at which a viscosity of 4800 Pa·s (48000 poises) was exhibited was measured.

[Production of Liquid Crystalline polyester (1)]

A reactor equipped with a stirring device, a torque meter, a nitrogen gas introduction tube, a thermometer and a reflux condenser was charged with 828.8 g (6.0 mol) of p-hydroxybenzoic acid, 473.4 g (2.85 mol) of terephthalic acid, 24.9 g (0.15 mol) of isophthalic acid, 558.6 g (3.0 mol) of 4,4′-dihydroxybiphenyl and 1347.6 g (13.2 mol) of acetic anhydride, the temperature was elevated from room temperature to 150° C. over 15 minutes under a nitrogen gas stream while stirring, and the mixture was refluxed at 150° C. for 3 hours. Then, the temperature was elevated from 150° C. to 320° C. over 2 hours and 50 minutes while acetic acid as a byproduct and unreacted acetic anhydride were distilled off, and at the point when increase in the torque was recognized, the content was taken out of the reactor and cooled to room temperature. The resulting solid matter was pulverized with a pulverizer, and the temperature was elevated from room temperature to 250° C. over 1 hour and from 250° C. to 320° C. over 5 hours under a nitrogen gas atmosphere, and was held at 320° C. for 3 hours for solid phase polymerization. Then, cooling was performed to obtain a powdery liquid crystalline polyester (1). This liquid crystalline polyester (1) had a repeating unit derived from p-hydroxybenzoic acid in an amount of 50 mol %, a repeating unit derived from terephthalic acid in an amount of 23.75 mol %, a repeating unit derived from isophthalic acid in an amount of 1.25 mol %, and a repeating unit derived from 4,4′-4,4′-dihydroxybiphenyl in an amount of 25 mol % relative to the total amount of all repeating units, and a flow initiation temperature of 380° C.

[Production of Liquid Crystalline polyester (2)]

A reactor equipped with a stirring device, a torque meter, a nitrogen gas introduction tube, a thermometer and a reflux condenser was charged with 994.5 g (7.2 mol) of p-hydroxybenzoic acid, 299.0 g (1.8 mol) of terephthalic acid, 99.7 g (0.6 mol) of isophthalic acid, 446.9 g (2.4 mol) of 4,4′-dihydroxybiphenyl, 1347.6 g (13.2 mol) of acetic anhydride and 0.18 g of 1-methylimidazole, the temperature was elevated from room temperature to 150° C. over 30 minutes under a nitrogen gas stream while stirring, and the mixture was refluxed at 150° C. for 30 minutes. Then, 2.4 g of 1-methylimidazole was added, the temperature was elevated from 150° C. to 320° C. over 2 hours and 50 minutes while acetic acid as a byproduct and unreacted acetic anhydride were distilled off, and at the point when increase in the torque was recognized, the content was taken out of the reactor and cooled to room temperature. The resulting solid matter was pulverized with a pulverizer, and the temperature was elevated from room temperature to 250° C. over 1 hour and from 250° C. to 295° C. over 5 hours under a nitrogen gas atmosphere, and was held at 295° C. for 3 hours for solid phase polymerization. Then, cooling was performed to obtain a powdery liquid crystalline polyester (2). This liquid crystalline polyester (2) had a repeating unit derived from p-hydroxybenzoic acid in an amount of 60 mol %, a repeating unit derived from terephthalic acid in an amount of 15 mol %, a repeating unit derived from isophthalic acid in an amount of 5 mol %, and a repeating unit derived from 4,4′-4,4′-dihydroxybiphenyl in an amount of 20 mol % relative to the total amount of all repeating units, and a flow initiation temperature of 330° C.

[Production of Liquid Crystalline polyester (3)]

A reactor equipped with a stirring device, a torque meter, a nitrogen gas introduction tube, a thermometer and a reflux condenser was charged with 994.5 g (7.2 mol) of p-hydroxybenzoic acid, 239.2 g (1.44 mol) of terephthalic acid, 159.5 g (0.96 mol) of isophthalic acid, 446.9 g (2.4 mol) of 4,4′-dihydroxybiphenyl, 1347.6 g (13.2 mol) of acetic anhydride and 0.18 g of 1-methylimidazole, the temperature was elevated from room temperature to 150° C. over 30 minutes under a nitrogen gas stream while stirring, and the mixture was refluxed at 150° C. for 30 minutes. Then, 2.4 g of 1-methylimidazole was added, the temperature was elevated from 150° C. to 320° C. over 2 hours and 50 minutes while acetic acid as a byproduct and unreacted acetic anhydride were distilled off, and at the point when increase in the torque was recognized, the content was taken out of the reactor and cooled to room temperature. The resulting solid matter was pulverized with a pulverizer, and the temperature was elevated from room temperature to 220° C. over 1 hour and from 220° C. to 240° C. over 30 minutes under a nitrogen gas atmosphere, and was held at 240° C. for 10 hours for solid phase polymerization. Then, cooling was performed to obtain a powdery liquid crystalline polyester (3). This liquid crystalline polyester (3) had a repeating unit derived from p-hydroxybenzoic acid in an amount of 60 mol %, a repeating unit derived from terephthalic acid in an amount of 12 mol %, a repeating unit derived from isophthalic acid in an amount of 8 mol %, and a repeating unit derived from 4,4′-4,4′-dihydroxybiphenyl in an amount of 20 mol % relative to the total amount of all repeating units, and a flow initiation temperature of 290° C.

### [Glass Fiber]

As a glass fiber, the following fibers were used. Glass fiber (1): “REVS” manufactured by Nippon Sheet Glass Co., Ltd. (number average fiber diameter 13 μm, number average fiber length 70 μm)

Glass fiber (2): “EFH75-01” manufactured by Central Glass Co., Ltd. (number average fiber diameter 11 μm, number average fiber length 75 μm)

### Experimental Examples 1 and 2, Comparative Experimental Example 1

The liquid crystalline polyester (1), (2) or (3) and the glass fiber (1) or (2) were mixed at a ratio shown in Table 1, and the mixture was granulated at a cylinder temperature of 390° C. (liquid crystalline polyester (1)), 340° C. (liquid crystalline polyester (2)) or 300° C. (liquid crystalline polyester (3)) using a twin screw extruder (“PCM-30” manufactured by Ikegai Corp.) to obtain a pellet-like liquid crystalline polyester composition. The resulting liquid crystalline polyester composition was injection-molded to obtain a molded product of 64 mm×64 mm×0.5 mm in thickness, a molded product of 100 mm×100 mm×1.0 mm in thickness and a molded product of 100 mm×100 mm×1.6 mm in thickness. On the resulting molded products, the breakdown voltage was measured at room temperature by a short time breakdown test method according to JIS C2110. The results are shown in Table 1.

TABLE 1

| | | | | | | | | Comparative | | |
|---|---|---|---|---|---|---|---|---|---|---|
| | | Experimental | | | Experimental | | | Experimental | | |
| Example | | Example 1 | | | Example 2 | | | Example 1 | | |
| Liquid crystalline polyester | (1) | 100 | | | — | | | — | | |
| (parts by mass) | (2) | — | | | 100 | | | — | | |
| | (3) | — | | | — | | | 100 | | |
| Glass fiber | (1) | 67 | | | — | | | — | | |
| (parts by mass) | (2) | — | | | 67 | | | 67 | | |
| Molded product thickness | (mm) | 0.5 | 1.0 | 1.6 | 0.5 | 1.0 | 1.6 | 0.5 | 1.0 | 1.6 |
| Breakdown voltage | (kV/mm) | 53.8 | 40.1 | 38.2 | 51.8 | 45.8 | 37.3 | 38.4 | 30.3 | 23.2 |

### DESCRIPTION OF REFERENCE NUMERALS

1 Power element
Printed wiring board
3 Terminal
4 Terminal-holding member
5 Heat radiating plate
6 Sealing material
7 Pad
8 Terminal-holding member also functioning as sealing material

1. A power device having a power element, a terminal, and a terminal-holding member composed of a liquid crystalline polyester, wherein the liquid crystalline polyester is a liquid crystalline polyester having a repeating unit (1) derived from an aromatic hydroxycarboxylic acid, a repeating unit (2) derived from an aromatic dicarboxylic acid, and a repeating unit (3) derived from an aromatic diol, and the content of a repeating unit derived from isophthalic acid in the liquid crystalline polyester is 0 to 7 mol % relative to the total amount of all repeating units of the liquid crystalline polyester.

2. The power device according to claim 1, wherein the repeating unit (1) is a repeating unit derived from p-hydroxybenzoic acid or 6-hydroxy-2-naphthoic acid, the repeating unit (2) is a repeating unit derived from terephthalic acid, isophthalic acid or 2,6-naphthalenedicarboxylic acid, and the repeating unit (3) is a repeating unit derived from hydroquinone or 4,4′-dihydroxybiphenyl.

3. The power device according to claim 1, wherein the liquid crystalline polyester is a liquid crystalline polyester having the repeating unit (1) in an amount of 30 to 80 mol %, the repeating unit (2) in an amount of 10 to 35 mol %, and the repeating unit (3) in an amount of 10 to 35 mol % relative to the total amount of all repeating units of the liquid crystalline polyester.

4. The power device according to claim 1, wherein the terminal-holding member is a member containing a glass fiber.

5. The power device according to claim 4, wherein the content of the glass fiber in the terminal-holding member is 10 to 100 parts by mass relative to 100 parts by mass of the liquid crystalline polyester.

6. The power device according to claim 1, wherein the distance between the adjacent terminals is 0.2 to 1.5 mm.

7. A package for a power device having a terminal, and a terminal-holding member composed of a liquid crystalline polyester, wherein the liquid crystalline polyester is a liquid crystalline polyester having a repeating unit (1) derived from an aromatic hydroxycarboxylic acid, a repeating unit (2) derived from an aromatic dicarboxylic acid, and a repeating unit (3) derived from an aromatic diol, and the content of a repeating unit derived from isophthalic acid in the liquid crystalline polyester is 0 to 7 mol % relative to the total amount of all repeating units of the liquid crystalline polyester.

8. The package for a power device according to claim 7, wherein the repeating unit (1) is a repeating unit derived from p-hydroxybenzoic acid or 6-hydroxy-2-naphthoic acid, the repeating unit (2) is a repeating unit derived from terephthalic acid, isophthalic acid or 2,6-naphthalenedicarboxylic acid, and the repeating unit (3) is a repeating unit derived from hydroquinone or 4,4′-dihydroxybiphenyl.

9. The package for a power device according to claim 7, wherein the liquid crystalline polyester is a liquid crystalline polyester having the repeating unit (1) in an amount of 30 to 80 mol %, the repeating unit (2) in an amount of 10 to 35 mol %, and the repeating unit (3) in an amount of 10 to 35 mol % relative to the total amount of all repeating units of the liquid crystalline polyester.

10. The package for a power device according to claim 7, wherein the terminal-holding member is a member containing a glass fiber.

11. The package for a power device according to claim 10, wherein the content of the glass fiber in the terminal-holding member is 10 to 100 parts by mass relative to 100 parts by mass of the liquid crystalline polyester.

12. The package for a power device according to claim 7, wherein the distance between the adjacent terminals is 0.2 to 1.5 mm.
